(19) United States
(12) Patent Application Publication
(10) Pub. No.: US 2026/0052620 A1
(43) Pub. Date: Feb. 19, 2026

(54) WIRING BOARD

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventor: Shinnosuke NAKAGUCHI, Mie (JP)

(21) Appl. No.: 19/102,409

(22) PCT Filed: Aug. 8, 2023
(86) PCT No.: PCT/JP2023/028879

§ 371 Date: Feb. 10, 2025

(30) Foreign Application Priority Data
Aug. 29, 2022 (JP) 2022-135730

(51) Int. Cl. H05K 1/02; H05K 1/11

(52) U.S. Cl. CPC H05K 1/0203; H05K 1/116; H05K 2201/066; H05K 2201/10522

(57) ABSTRACT

A wiring board includes a board portion and a conductor portion. The board portion includes a conductor layer having a wiring pattern (first wiring pattern) and an insulation layer having an insulation film for covering a part of the wiring pattern, and a partial region of the wiring pattern is configured as a land portion. The conductor portion includes a base material and a plating layer. The base material has a facing surface, a pair of first surfaces and a pair of second surfaces. The facing surface and the pair of facing surfaces are covered by the plating layer. The pair of second surfaces have exposing surfaces. The plating layer covering the pair of first surfaces is joined to the land portion. The pair of second surfaces are arranged to overlap the land portion in a thickness direction.

### TECHNICAL FIELD

The present disclosure relates to a wiring board.

### BACKGROUND

Patent Document 1 discloses a heat dissipation structure of a surface-mounted electronic component. Specifically, a heat generating component to be surface-mounted on a printed board and an SMT radiator arranged on a wiring pattern near the heat generating component are disclosed. The SMT radiator is made of metal good in thermal conductivity and functions as a heat dissipating component. The SMT radiator has a rectangular parallelepiped shape and the lower surface thereof is soldered to the wiring pattern.

### PRIOR ART DOCUMENT

### Patent Document

Patent Document 1: JP. 2003-188565 A

### SUMMARY OF THE INVENTION

### Problems to be Solved

A conductor portion such as the SMT radiator in Patent Document 1 is, for example, composed of a base material and a plating layer covering the base material, and the plating layer is soldered to the wiring pattern. Such a conductor portion is joined to the wiring pattern not only on the lower surface, but also on four surfaces rising from the lower surface, whereby joint strength to the wiring pattern is further enhanced. However, to join the above four surfaces to the wiring pattern, a land portion formed by an exposed part of the wiring pattern needs to be formed to protrude outward from the outer peripheral edge of the lower surface of the conductor portion and the above four surfaces need to be joined to this protruding part. Thus, it becomes difficult to arrange the base material near ends of the land portion.

One object of the present disclosure is to provide a technique for easily placing a base material of a conductor portion near an end in a predetermined direction of a land portion while improving the joint strength of the conductor portion to a wiring pattern.

### Means to Solve the Problem

The present disclosure is directed to a wiring board with a board portion including a conductor layer having a wiring pattern and an insulation layer having an insulation film for covering a part of the wiring pattern, a partial region of the wiring pattern being configured as a land portion not covered by the insulation film, and a conductor portion to be joined to the land portion by solder, the conductor portion including an electrically conductive base material and a plating layer covering a part of the base material, the base material having a facing surface facing the land portion on one side in a thickness direction of the board portion, a pair of first surfaces arranged on both sides in a first direction orthogonal to the thickness direction and a pair of second surfaces arranged on both sides in a second direction orthogonal to the thickness direction and the first direction, the facing surface and the pair of first surfaces being covered by the plating layer, the pair of second surfaces having exposing surfaces where the base material is exposed without being covered by the plating layer, the plating layer covering the pair of first surfaces being joined to the land portion by the solder, and the pair of second surfaces being arranged to overlap the land portion in the thickness direction.

### Effect of the Invention

The technique according to the present disclosure enables a base material of a conductor portion to be easily placed near an end in a predetermined direction of a land portion while improving the joint strength of the conductor portion to a wiring pattern.

### BRIEF DESCRIPTION OF THE DRAWINGS

FIG. 1 is a plan view of a wiring board in a first embodiment.

FIG. 2 is a front view of the wiring board in the first embodiment.

FIG. 3 is a section along A-A of FIG. 1 near a conductor portion.

FIG. 4 is a section along B-B of FIG. 2 near the conductor portion

FIG. 5 is a plan view enlargedly showing near a conductor portion of a wiring board in a second embodiment.

FIG. 6 is a section along C-C of FIG. 5.

FIG. 7 is a plan view enlargedly showing near a conductor portion of a wiring board in a third embodiment.

FIG. 8 is a section along D-D of FIG. 7.

### DETAILED DESCRIPTION TO EXECUTE THE INVENTION

Hereinafter, embodiments of the present disclosure are listed and described.

[1] A wiring board is provided with a board portion including a conductor layer having a wiring pattern and an insulation layer having an insulation film for covering a part of the wiring pattern, a partial region of the wiring pattern being configured as a land portion not covered by the insulation film, and a conductor portion to be joined to the land portion by solder, the conductor portion including an electrically conductive base material and a plating layer covering a part of the base material, the base material having a facing surface facing the land portion on one side in a thickness direction of the board portion, a pair of first surfaces arranged on both sides in a first direction orthogonal to the thickness direction and a pair of second surfaces arranged on both sides in a second direction orthogonal to the thickness direction and the first direction, the facing surface and the pair of first surfaces being covered by the plating layer, the pair of second surfaces having exposing surfaces where the base material is exposed without being covered by the plating layer, the plating layer covering the pair of first surfaces being joined to the land portion by the solder, and the pair of second surfaces being arranged to overlap the land portion in the thickness direction.

Since the plating layer covering the pair of first surfaces is joined to the land portion by the solder in the wiring board, the joint strength of the conductor portion to the land portion can be improved. On the other hand, the pair of second surfaces have the exposing surfaces and are arranged to overlap the land portion in the thickness direction. That is, since at least parts of the pair of second surfaces are not covered by the plating layer in the wiring board, the wiring board is accordingly less likely to interfere with other members, with the result that the base material is easily placed near an end in the second direction of the land portion.

[2] In the wiring board of [1] described above, a distance in the second direction from at least either one of the second surfaces to an end of the land portion is shorter than a distance in the first direction from either one of the first surfaces to an end of the land portion.

In the above wiring board, at least one second surface can be brought closer to the end in the second direction of the land portion by a distance shorter than a distance from either one of the first surfaces to an end in the first direction of the land portion. [3] In the wiring board of [1] or [2] described above, the conductor portion is arranged over a plurality of the land portions separated from each other and joined to each of the plurality of land portions.

In the above wiring board, the conductor portion can be intensively joined at a plurality of positions.

[4] In the wiring board of [3] described above, the solder is continuously arranged over the plurality of separated land portions between the board portion and the facing surface.

The joint strength of the entire solder can be enhanced by the solder continuously arranged over the plurality of land portions while the conductor portion is intensively joined at the plurality of positions.

[5] In the wiring board of any one of [1] to [4] described above, the entire facing surface of the conductor portion is provided to overlap the land portion.

In the above wiring board, the joint strength to the land portion easily becomes uniform on the entire facing surface.

[6] In the wiring board of any one of [1] to [5] described above, an area of each of the pair of first surfaces is larger than an area of each of the pair of second surfaces.

In the above wiring board, the joint strength of the first surface and the land portion is easily improved while the enlargement of the conductor portion is suppressed. [7] In the wiring board of any one of [1] to [6] described above, the conductor portion has a longitudinal shape extending along a current flowing direction in a part where the conductor portion is joined.

Since a current easily flows in the conductor portion in the wiring board, the heat dissipation performance of the conductor portion can be improved.

[8] In the wiring board of any one of [1] to [7] described above, a height of a fillet of the solder joined to at least either one of the first surfaces and the land portion is higher than a height of a center position in the thickness direction of the first surface joined to the fillet from the land portion.

In the above wiring board, the joint strength of at least either one of the first surfaces and the land portion can be further improved.

### First Embodiment

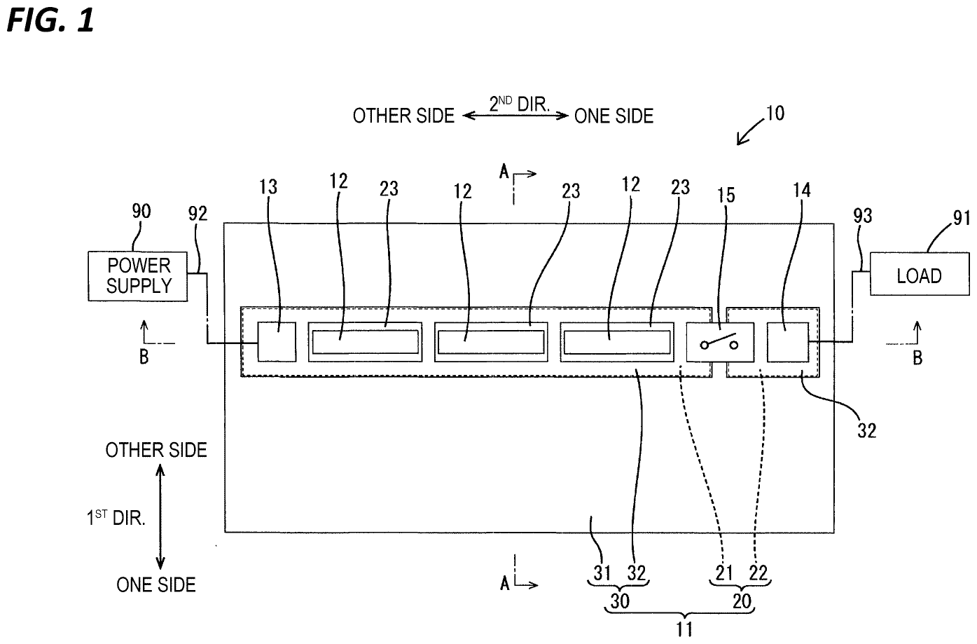

A wiring board 10 shown in FIG. 1 is, for example, installed in an unillustrated vehicle. The wiring board 10 is provided between a power supply 90 and a load 91 installed in the vehicle and functions as a power line for supplying power based on the power supply toward the load 91.

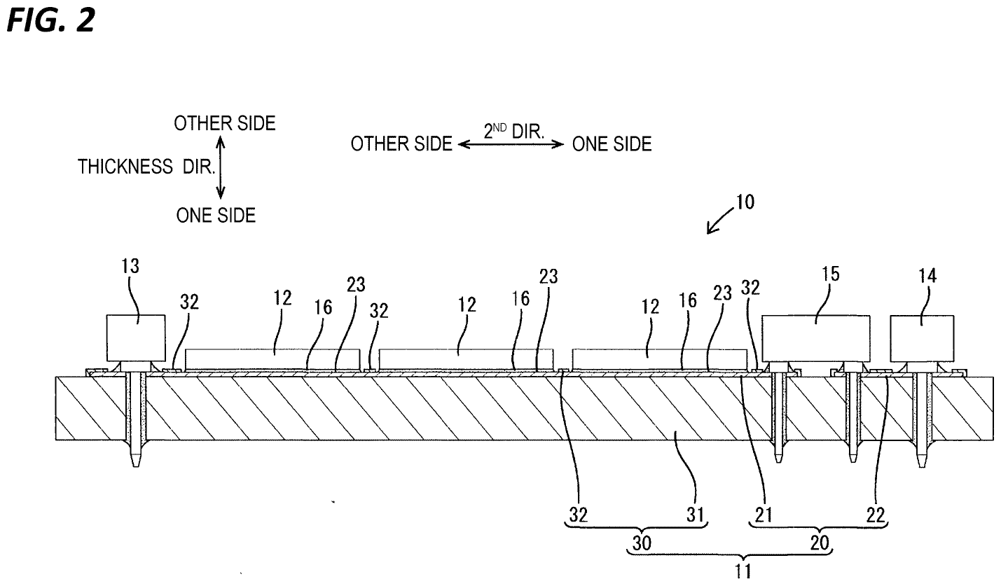

The wiring board 10 is, as shown in FIGS. 1 and 2, provided with a board portion 11, conductor portions 12, an input portion 13, an output portion 14, a switch portion and solder 16. Note that the solder 16 is not shown in FIG. 1.

The board portion 11 includes a conductor layer 20 and an insulation layer 30. The conductor layer 20 is provided between the power supply 90 and the load 91 and functions as a power line for supplying the power based on the power supply 90 toward the load 91. The input portion 13, the output portion 14 and the switch portion 15 are provided on the conductor layer 20.

The input portion 13, the output portion 14 and the switch portion 15 are electrically joined to the conductor layer 20, for example, by soldering. The input portion 13 is, for example, configured as a connector and connected to the power supply 90 via a wiring 92. The power based on the power supply 90 is supplied to the input portion 13. The power supplied to the input portion 13 is supplied to the output portion 14 via the conductor layer 20.

The output portion 14 is, for example, configured as a connector and connected to the load 91 via a wiring 93. The power based on the power supply 90 is supplied to the load 91 via the input portion 13, the conductor layer 20 and the output portion 14.

The switch portion 15 may be configured to include a switch having a physical contact point or may be configured to include a semiconductor switching element. The switch portion 15 is provided between the input portion 13 and the output portion 14. The switch portion 15 allows power supply from the side of the input portion 13 to the side of the output portion 14 when being in an ON state. The switch portion 15 cuts off the power supply from the side of the input portion 13 to the side of the output portion 14 when being in an OFF state.

The conductor layer 20 is, for example, constituted by a metal foil (e.g. copper foil). The conductor layer 20 includes a first wiring pattern 21 and a second wiring pattern 22. The first and second wiring patterns 21, 22 are arranged apart from each other. The first wiring pattern 21 has a longitudinal shape. The input portion 13 is provided on one end side of the first wiring pattern 21. One end of the switch portion 15 is provided on the other end side of the first wiring pattern 21. The other end of the switch portion 15 and the output portion 14 are provided on the second wiring pattern 22.

The insulation layer 30 includes a board body 31 and an insulation film 32. The board body 31 has an insulating property and is, for example, made of resin. The board body 31 is plate-like. The board body 31 is arranged on one side in a thickness direction of the board portion 11 with respect to the conductor layer 20. The “thickness direction of the board portion 11” is merely referred to as the “thickness direction” below. The conductor layer 20 (more specifically, the first and second wiring patterns 21, 22) is provided on a surface of the board body 31 on the other side in the thickness direction. The insulation film 32 covers a part of a surface of the conductor layer 20 (more specifically, the first and second wiring patterns 21, 22) on the other side in the thickness direction. The insulation film 32 is, for example, configured as a solder resist. The insulation film 32 has an insulating property and is, for example, made of resin.

Partial regions of the first wiring pattern 21 are configured as land portions 23 not covered by the insulation film 32. The land portions 23 are surrounded by the insulation film 32. The land portions 23 have a rectangular shape. The land portions 23 have a longitudinal shape extending along a current flowing direction. The land portions 23 have a longitudinal shape extending along a longitudinal direction of the first wiring pattern 21. The land portions 23 are arranged between the input portion 13 and the output portion 14 and between the input portion 13 and the switch portion 15. A plurality of the land portions 23 are provided. The plurality of land portions 23 are arranged apart from each other. The plurality of land portions 23 are separated in the current flowing direction. The plurality of land portions 23 are separated in the longitudinal direction of the first wiring pattern 21.

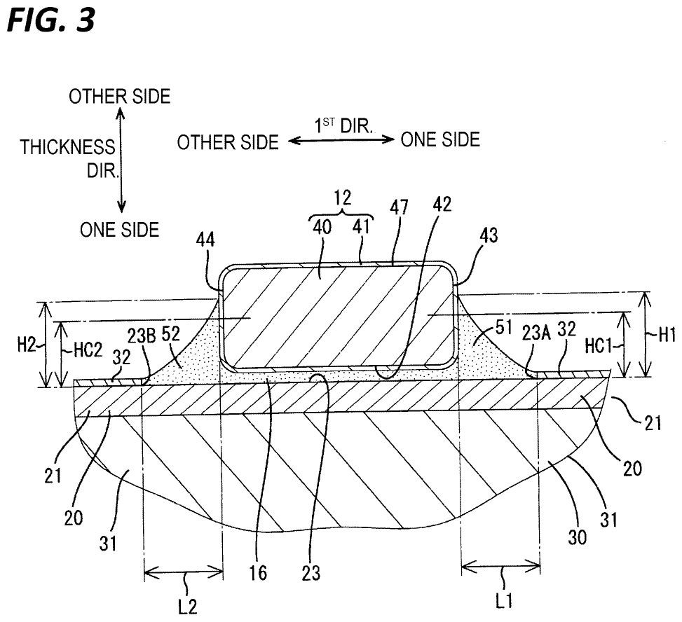

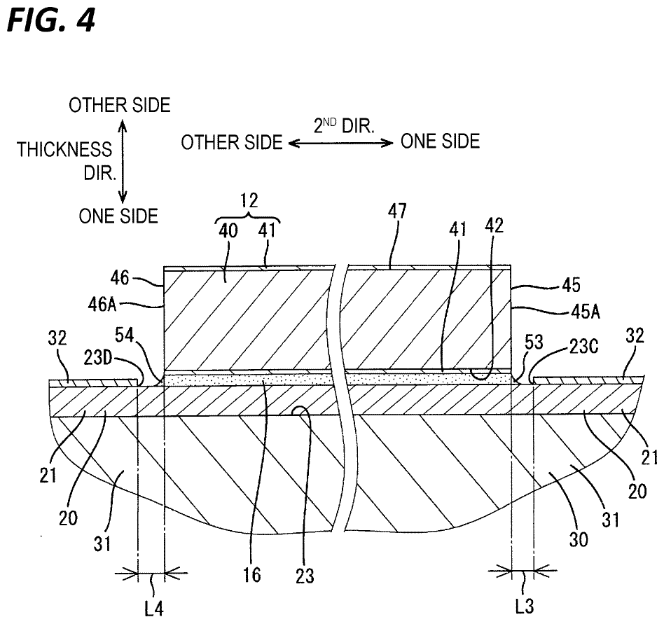

As shown in FIGS. 3 and 4, the conductor portion 12 is a member to be joined to the land portion 23 by the solder 16. The conductor portion 12 functions as a heat dissipating member. The conductor portion 12 is, for example, configured as a chip busbar. The conductor portion 12 has a rectangular parallelepiped shape in this embodiment, but may have another shape. For example, the conductor portion 12 may have a cubic shape or may be formed to have a curved surface. The conductor portion 12 includes an electrically conductive base material 40 and a plating layer 41 covering a part of the base material 40. The base material 40 is a member not joined to the solder 16 or a member less likely to be joined to the solder 16 than the plating layer 41. The plating layer 41 is a member to be joined to the solder 16 and a member more easily joined to the solder 16 than the base material 40.

The base material 40 has a facing surface 42, a pair of first surfaces 43, 44, a pair of second surfaces 45, 46 and a ceiling surface 47.

The facing surface 42 is facing the land portion 23 on one side in the thickness direction. The facing surface 42 is facing the conductor layer 20 via the solder 16 or directly. The facing surface 42 may or may not be in contact with the conductor layer 20.

The pair of first surfaces 43, 44 are arranged on both sides in a first direction of the base material 40. The first direction is a direction orthogonal to the thickness direction. One first surface 43 is arranged on one side in the first direction of the base material 40. The other first surface 44 is arranged on the other side in the first direction of the base material 40.

The pair of second surfaces 45, 46 are arranged on both sides in a second direction of the base material 40. The second direction is a direction orthogonal to the thickness direction and the first direction. One second surface 45 is arranged on one side in the second direction of the base material 40. The other second surface 46 is arranged on the other side in the second direction of the base material 40.

The ceiling surface 47 is arranged on a side opposite to the facing surface 42 in the base material 40. The ceiling surface 47 is arranged on the other side in the thickness direction of the base material 40.

A length in the first direction of the conductor portion 12 is shorter than a length in the second direction of the conductor portion 12. A length in the thickness direction of the conductor portion 12 is shorter than a length in the first direction of the conductor portion 12 and shorter than a length in the second direction of the conductor portion 12.

The facing surface 42, the pair of first surfaces 43, 44, the pair of second surfaces 45, 46 and the ceiling surface 47 are flat surfaces. The flat surfaces include not only surfaces, which are strictly flat, but also slightly curved surfaces. The facing surface 42, the pair of first surfaces 43, 44 and the ceiling surface 47 are covered by the plating layer 41. The plating layer 41 covering the facing surface 42, the pair of first surfaces 43, 44 and the ceiling surface 47 is continuous and has an annular shape. The plating layer 41 covering the facing surface 42 and the pair of first surfaces 43 44 is joined to the land portion 23 by the solder 16. That is, the facing surface 42 and the pair of first surfaces 43, 44 are joined to the solder 16 via the plating layer 41.

In a projection plane obtained by projecting the facing surface 42, the solder 16 and the land portion 23 to a virtual plane orthogonal to the thickness direction, a ratio of an area of a region where the facing surface 42, the solder 16 and the land portion 23 overlap each other to an area of the facing surface 42 is desirably 50% or more, more desirably 80% or more. According to this configuration, the wiring board 10 can further improve the joint strength of the conductor portion 12 and the land portion 23. In this embodiment, the above ratio is 100% (see FIGS. 1, 3 and 4).

The pair of second surfaces 45, 46 have exposing surfaces 45A, 46A where the base material 40 is exposed without being covered by the plating layer 41. In this embodiment, the entire second surfaces 45, 46 are the exposing surfaces 45A, 46A. The exposing surfaces 45A, 46A are joined to neither the solder 16 nor the land portion 23. The pair of second surfaces 45, 46 are arranged to overlap the land portion 23 in the thickness direction.

According to this configuration, since the plating layer 41 covering the pair of first surfaces 43, 44 is joined to the land portion 23 by the solder 16 in the wiring board 10, the joint strength of the conductor portion 12 to the land portion 23 can be improved. On the other hand, the pair of second surfaces 45, 46 have the exposing surfaces 45A, 46A and are arranged to overlap the land portion 23 in the thickness direction. That is, since at least parts of the pair of second surfaces 45, 46 are not covered by the plating layer 41 in the wiring board 10, the wiring board 10 is accordingly less likely to interfere with other members, with the result that the base material 40 is easily placed near ends 23C, 23D in the second direction of the land portion 23. Particularly, since the entire second surfaces 45, 46 are the exposing surfaces 45A, 46A in the wiring board 10 of this embodiment, the base material 40 is more easily placed near the ends 23C, 23D in the second direction of the land portion 23.

A distance in the second direction from at least either one of the second surfaces 45, 46 to the end of the land portion 23 is shorter than a distance in the first direction from either one of the first surfaces 43, 44 to the end of the land portion 23. The “end of the land portion 23” in “from the second surface 45 to the end of the land portion 23” means the “end 23C of the land portion 23 arranged in a facing direction of the second surface 45”. The “end of the land portion 23” in “from the second surface 46 to the end of the land portion 23” means the “end 23D of the land portion 23 arranged in a facing direction of the second surface 46”. The “end of the land portion 23” in “from the first surface 43 to the end of the land portion 23” means an “end 23A of the land portion 23 arranged in a facing direction of the first surface 43”. The “end of the land portion 23” in “from the first surface 44 to the end of the land portion 23” means an “end 23B of the land portion 23 arranged in a facing direction of the first surface 44”.

In an example shown in FIG. 3, the distance in the first direction from the first surface 43 to the end 23A of the land portion 23 is a distance L1, and the distance in the first direction from the first surface 44 to the end 23B of the land portion 23 is a distance L2. In an example shown in FIG. 4, the distance in the second direction from the second surface 45 to the end 23C of the land portion 23 is a distance L3, and the distance in the second direction from the second surface 46 to the end 23D of the land portion 23 is a distance L4. The distance L3 is shorter than the distances L1, L2. The distance L4 is shorter than the distances L1, L2. That is, the distances L3, L4 in the second direction from the second surfaces 45, 46 to the ends 23C, 23D of the land portion 23 are both shorter than the distances L1, L2 in the first direction from the first surfaces 43, 44 to the ends 23A, 23B of the land portion 23.

According to this configuration, the second surface 45 can be brought closer to the end 23C in the second direction of the land portion 23 by a distance shorter than the distances L1, L2 in the wiring board 10. Further, the second surface 46 can be brought closer to the end 23D in the second direction of the land portion 23 by a distance shorter than the distances L1, L2 in the wiring board 10.

Note that the distance L1 may be equal to or different from the distance L2. The distance L3 may be equal to or different from the distance L4.

The solder 16 is formed with fillets 51, 52, 53 and 54. The fillet 51 is arranged on one side in the first direction of the solder 16. The fillet 51 is joined to the first surface 43 and the land portion 23. The fillet 52 is arranged on the other side in the first direction of the solder 16. The fillet 52 is joined to the first surface 44 and the land portion 23. The fillet 53 is arranged on one side in the second direction of the solder 16. The fillet 53 is arranged at a position below the exposing surface 45A of the second surface 45 in the example shown in FIG. 4. Note that the fillet 53 may not be arranged at the position below the exposing surface 45A of the second surface 45. For example, the upper end of the fillet 53 may be arranged at a position above the lower end of the exposing surface 45A. The fillet 54 is arranged on the other side in the second direction of the solder 16. The fillet 54 is arranged at a position below the exposing surface 46A of the second surface 46 in the example shown in FIG. 4. Note that the fillet 54 may not be arranged at the position below the exposing surface 46A of the second surface 46. For example, the upper end of the fillet 54 may be arranged at a position above the lower end of the exposing surface 46A. A height of the fillet 51 may be equal to or higher than those of the fillets 53, 54. A height of the fillet 52 may be equal to or higher than those of the fillets 53, 54. A cross-section (more specifically, a cross-section cut in a direction orthogonal to the second direction) of the fillet 51, 52 has a triangular shape (more specifically, an isosceles triangular shape with two sides to be joined having an equal length). A cross-section (more specifically, a cross-section cut in a direction orthogonal to the first direction) of the fillet 53, 54 has a triangular shape (more specifically, an isosceles triangular shape with two sides to be joined having an equal length). The “two sides having an equal length” means not only a case where the two sides are strictly equal, but also a case where the two sides are substantially equal. “Substantially equal” means that a ratio of a difference between the lengths of the two sides to the length of the longer side, out of the two sides, is within 10%.

In the example shown in FIG. 3, a height of the fillet 51 of the solder 16 joined to the first surface 43 and the land portion 23 from the land portion 23 is a height H1. The height H1 is a height at the highest position of the fillet 51. A height of the fillet 52 of the solder 16 joined to the first surface 44 and the land portion 23 from the land portion 23 is a height H2. The height H2 is a height at the highest position of the fillet 52. A height of a center position in the thickness direction of the first surface 43 from the land portion 23 is a height HC1. The height HC1 is a height at a center position in the second direction of the first surface 43. A height of a center position in the thickness direction of the first surface 44 from the land portion 23 is a height HC2. The height HC2 is a height at a center position in the second direction of the first surface 44. The height is synonymous with a length in the thickness direction.

In the example shown in FIG. 3, the height H1 is higher than the height HC1. The height H2 is higher than the height HC2. According to this configuration, the joint strength of the first surfaces 43, 44 and the land portion 23 can be further improved in the wiring board 10.

Note that the height H1 may be equal to or lower than the height HC1. The height H2 may be equal to or lower than the height HC2. The height H1 may be higher than the height HC1 and the height H2 may be equal to or lower than the height HC2. The height H2 may be higher than the height HC2 and the height H1 may be equal to or lower than the height HC1.

The conductor portion 12 is joined to one land portion 23. In a planar direction orthogonal to the thickness direction, the conductor portion 12 is arranged inside the outer peripheral edge of the land portion 23. The entire facing surface 42 of the conductor portion 12 is provided to overlap the land portion 23. According to this configuration, the joint strength to the land portion 23 tends to be uniform over the entire facing surface 42 in the wiring board 10.

An area of each of the pair of respective first surfaces 43, 44 is larger than that of each of the pair of respective second surfaces 45, 46. According to this configuration, the joint strength of the first surfaces 43, 44 and the land portion 23 is easily improved in the wiring board 10 while the enlargement of the conductor portion 12 is suppressed.

The conductor portion 12 has a longitudinal shape extending along the current flowing direction in a part where the conductor portion 12 is joined. The “current flowing direction” is a direction from the side of the input portion 13 to the side of the output portion 14 in the conductor layer 20. According to this configuration, since a current easily flows in the conductor portion 12 in the wiring board 10, the heat dissipation performance of the conductor portion 12 can be improved.

The following description relates to a manufacturing method of the wiring board 10.

The board portion 11 is formed by printing the conductor layer 20 on the surface of the board body 31 and applying the insulation film 32 to partially cover the conductor layer 20. After the surface of a metal member in the form of a rectangular column is plated, this metal member is cut and divided in a direction orthogonal to an extension direction thereof, whereby the conductor portions 12 are formed. Cut surfaces are configured as the unplated second surfaces 45, 46. Solder cream is applied to the board portion 11, and the conductor portions 12, the input portion 13, the output portion 14 and the switch portion 15 are placed. Thereafter, the conductor portions 12, the input portion 13, the output portion 14 and the switch portion 15 are joined to the conductor layer 20 by the solder 16 by a reflow process. In this way, the wiring board 10 is manufactured.

### Second Embodiment

In the first embodiment, one conductor portion is joined to one land portion. In contrast, a configuration in which one conductor portion is joined to a plurality of land portions is described in a second embodiment. Note that, in the description of the second embodiment, the same components as those of the first embodiment are denoted by the same reference signs and not described in detail.

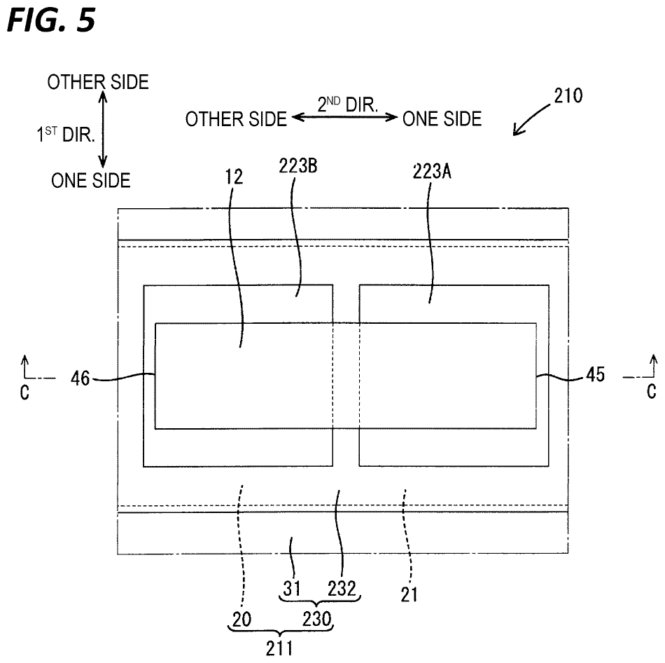

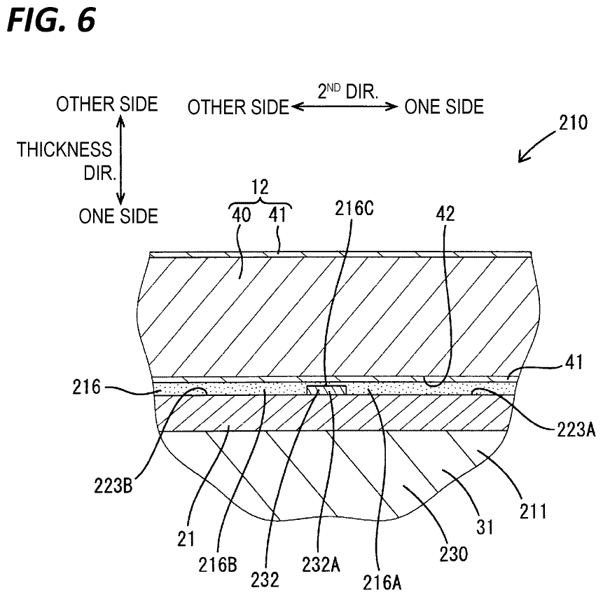

FIGS. 5 and 6 show a wiring board 210 of the second embodiment. The wiring board 210 is provided with a board portion 211, a conductor portion 12 and solder 216. The board portion 211 includes a conductor layer 20 and an insulation layer 230. Note that the solder 216 is not shown in FIG. 5.

As shown in FIGS. 5 and 6, the insulation layer 230 includes a board body 31 and an insulation film 232. The insulation film 232 has an insulating property and is, for example, made of resin. The insulation film 232 covers a part of a surface of the conductor layer 20 (more specifically, a first wiring pattern 21) on the other side in the thickness direction.

Partial regions of the first wiring pattern 21 in the conductor layer 20 are configured as land portions 223A, 223B not covered by the insulation film 232. Each of the land portions 223A, 223B is surrounded by the insulation film 232. Each of the land portions 223A, 223B has a rectangular shape. The land portions 223A, 223B are arranged side by side at an interval in a current flowing direction. The land portions 223A, 223B are arranged side by side at an interval in a longitudinal direction of the first wiring pattern 21. The land portions 223A, 223B are arranged between the input portion 13 and the output portion 14 and between the input portion 13 and the switch portion 15 described in the first embodiment.

The conductor portion 12 is arranged over a plurality of (two in this embodiment) land portions 223A, 223B separated from each other and joined to each of the plurality of land portions 223A, 223B by the solder 216. According to this configuration, the conductor portion 12 can be intensively joined at a plurality of positions in the wiring board 210. The plurality of (two in this embodiment) land portions 223A, 223B to be joined to one conductor portion 12 are constituted by the same wiring pattern (specifically, the first wiring pattern 21). One land portion 223A is arranged on one side in the second direction of the other land portion 223B. A second surface 45 is arranged to overlap the land portion 223A in the thickness direction. A second surface 46 is arranged to overlap the land portion 223B in the thickness direction.

The solder 216 is continuously arranged over the plurality of separated land portions 223A, 223B between the board portion 211 (more specifically, the board body 31) and a facing surface 42. The insulation film 232 includes an intermediate insulation film 232A to be arranged between the plurality of land portions 223A, 223B to be joined to one conductor portion 12. The solder 216 includes a first solder portion 216A for joining a plating layer 41 covering the facing surface 42 to the land portion 223A, a second solder portion 216B for joining the plating layer 41 covering the facing surface 42 to the land portion 223B and a third solder portion 216C arranged between the first and second solder portions 216A, 216B. The first solder portion 216A is arranged to overlap the facing surface 42 and the land portion 223A in the thickness direction. The second solder portion 216B is arranged to overlap the facing surface 42 and the land portion 223B in the thickness direction. The conductor portion 12 is arranged apart from the intermediate insulation film 232A in the thickness direction. The third solder portion 216C is arranged between the conductor portion 12 and the intermediate insulation film 232A in the thickness direction and links the first and second solder portions 216A, 216B. The third solder portion 216C is joined to the plating layer 41 covering the facing surface 42.

According to this configuration, the joint strength of the entire solder 216 can be enhanced by the solder 216 continuously arranged over the plurality of land portions 223A, 223B in the wiring board 210 while the conductor portion 12 is intensively joined at the plurality of positions.

### Third Embodiment

In the second embodiment, one conductor portion is joined to the plurality of land portions and the plurality of land portions are constituted by the same wiring pattern. In a third embodiment, an example in which a plurality of land portions are constituted by separate wiring patterns is described. Note that, in the description of the third embodiment, the same components as those of the first embodiment are denoted by the same reference signs and not described in detail.

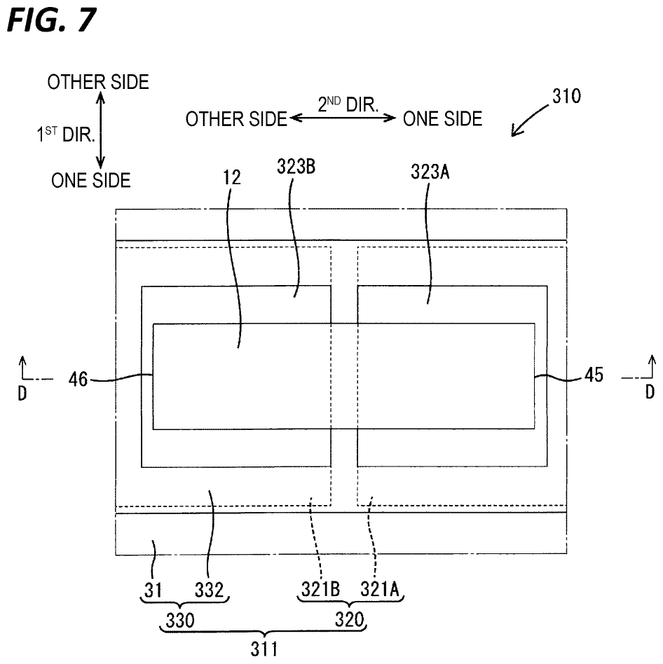

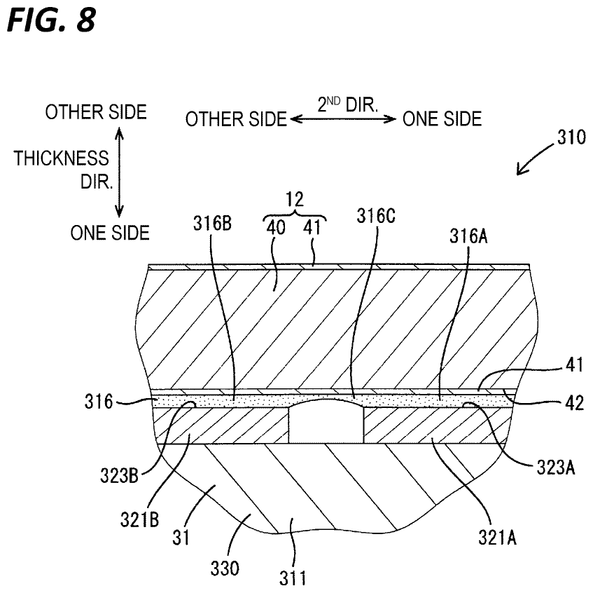

FIGS. 7 and 8 show a wiring board 310 of the third embodiment. The wiring board 310 is provided with a board portion 311, a conductor portion 12 and solder 316. The board portion 311 includes a conductor layer 320 and an insulation layer 330. Note that the solder 316 is not shown in FIG. 7.

The conductor layer 320 includes a plurality of (two in this embodiment) wiring patterns 321A, 321B to be joined to one conductor portion 12. The plurality of wiring patterns 321A, 321B constitute a path between the input portion 13 and the switch portion 15 described in the first embodiment (see FIG. 1). The plurality of wiring patterns 321A, 321B are arranged apart from each other in the second direction. A space is formed between the plurality of wiring patterns 321A, 321B. One wiring pattern 321A is arranged on one side in the second direction of the other wiring pattern 321B.

As shown in FIGS. 7 and 8, the insulation layer 330 includes a board body 31 and an insulation film 332. The insulation film 332 has an insulating property and is, for example, made of resin. The insulation film 332 covers a part of a surface of the conductor layer 320 (more specifically, the wiring patterns 321A, 321B) on the other side in the thickness direction.

A partial region of the wiring pattern 321A is configured as a land portion 323A not covered by the insulation film 332. A partial region of the wiring pattern 321B is configured as a land portion 323B not covered by the insulation film 332. Each of the land portions 323A, 323B has a rectangular shape. The land portions 323A, 323B are arranged apart from each other in a current flowing direction.

The conductor portion 12 is arranged over a plurality of (two in this embodiment) the land portions 323A, 323B separated from each other and joined to each of the plurality of land portions 323A, 323B by the solder 316. According to this configuration, the conductor portion 12 can be intensively joined at a plurality of positions in the wiring board 310. The plurality of (two in this embodiment) land portions 323A, 323B to be joined to one conductor portion 12 are constituted by the separate wiring patterns. One land portion 323A is arranged on one side in the second direction of the other land portion 323B. A second surface 45 is arranged to overlap the land portion 323A in the thickness direction. A second surface 46 is arranged to overlap the land portion 323B in the thickness direction.

The solder 316 is continuously arranged over the plurality of separated land portions 323A, 323B between the board portion 311 (more specifically, the board body 31) and a facing surface 42. The solder 316 includes a first solder portion 316A for joining a plating layer 41 covering the facing surface 42 to the land portion 323A, a second solder portion 316B for joining the plating layer 41 covering the facing surface 42 to the land portion 323B and a third solder portion 316C arranged between the first and second solder portions 316A, 316B. The first solder portion 316A is arranged to overlap the facing surface 42 and the land portion 323A in the thickness direction. The second solder portion 316B is arranged to overlap the facing surface 42 and the land portion 323B in the thickness direction. The third solder portion 316C is arranged at a position above the space between the plurality of wiring patterns 321A, 321B. The third solder portion 316C links the first and second solder portions 316A, 316B. The third solder portion 316C is joined to the plating layer 41 covering the facing surface 42. The solder 316 is in the form of a bridge extending over the plurality of land portions 323A, 323B.

According to this configuration, the joint strength of the entire solder 316 can be enhanced by the solder 316 continuously arranged over the plurality of land portions 323A, 323B in the wiring board 310 while the conductor portion 12 is intensively joined at the plurality of positions. Moreover, the conductor portion 12 also functions as a path linking the wiring patterns 321A, 321B.

### Other Embodiments

The present disclosure is not limited to the above described and illustrated embodiments. For example, features of the above embodiments or embodiments described below can be combined in every way without contradiction. Further, any of the features of the above embodiments or the embodiments described below can be omitted unless being expressly stated as essential. Further, the aforementioned embodiments may be modified as follows.

The length in the first direction of the conductor portion 12 may be longer than or equal to that in the second direction of the conductor portion 12. Here, “equal” means not only strictly equal, but also substantially equal. Substantially equal means that a ratio of a difference between the length in the first direction and the length in the second direction to the longer length is within 5%.

The length in the thickness direction of the conductor portion 12 may be longer than or equal to that in the first direction of the conductor portion 12. Here, “equal” means not only strictly equal, but also substantially equal. Substantially equal means that a ratio of a difference between the length in the thickness direction and the length in the first direction to the longer length is within 5%.

The length in the thickness direction of the conductor portion 12 may be longer than or equal to that in the second direction of the conductor portion 12. Here, “equal” means not only strictly equal, but also substantially equal. Substantially equal means that a ratio of a difference between the length in the thickness direction and the length in the second direction to the longer length is within 5%.

The solder 16, 216, 316 may not be formed with the fillets 53, 54.

Note that the embodiments disclosed this time should be considered illustrative in all aspects, rather than restrictive. The scope of the present invention is not limited to the embodiments disclosed this time and is intended to include all changes in the scope of claims or in the scope of equivalents to claims.

### LIST OF REFERENCE NUMERALS

10 wiring board
11 . . . board portion
12 . . . conductor portion
13 . . . input portion
14 . . . output portion
15 . . . switch portion
16 . . . solder
20 . . . conductor layer
21 . . . first wiring pattern (wiring pattern)
22 . . . second wiring pattern
23 . . . land portion
23A . . . end
23B . . . end
23C . . . end
23D . . . end
30 . . . insulation layer
31 . . . board body
32 . . . insulation film
40 . . . base material
41 . . . plating layer
42 . . . facing surface
43 . . . first surface
44 . . . first surface
45 . . . second surface
45A . . . exposing surface
46 . . . second surface
46A . . . exposing surface
47 . . . ceiling surface
51 . . . fillet
52 . . . fillet
53 . . . fillet
54 . . . fillet
90 . . . power supply
91 . . . load
92 . . . wiring
93 . . . wiring
210 . . . wiring board
211 . . . board portion
216 . . . solder
216A . . . first solder portion
216B . . . second solder portion
216C . . . third solder portion
223A . . . land portion
223B . . . land portion
230 . . . insulation layer
232 . . . insulation film
232A . . . intermediate insulation film
310 . . . wiring board
311 . . . board portion
316 . . . solder
316A . . . first solder portion
316B . . . second solder portion
316C . . . third solder portion
320 . . . conductor layer
321A . . . wiring pattern
321B . . . wiring pattern
322 . . . insulation film
323A . . . land portion
323B . . . land portion
330 . . . insulation layer
332 . . . insulation film
H1 . . . height
H2 . . . height
HC1 . . . height
HC2 . . . height
L1 . . . distance
L2 . . . distance
L3 . . . distance
. . . L4 distance

1. A wiring board, comprising:
a board portion including a conductor layer having a wiring pattern and an insulation layer having an insulation film for covering a part of the wiring pattern, a partial region of the wiring pattern being configured as a land portion not covered by the insulation film; and
a conductor portion to be joined to the land portion by solder,
the conductor portion including an electrically conductive base material and a plating layer covering a part of the base material,
the base material having a facing surface facing the land portion on one side in a thickness direction of the board portion, a pair of first surfaces arranged on both sides in a first direction orthogonal to the thickness direction and a pair of second surfaces arranged on both sides in a second direction orthogonal to the thickness direction and the first direction,
the facing surface and the pair of first surfaces being covered by the plating layer,
the pair of second surfaces having exposing surfaces where the base material is exposed without being covered by the plating layer,
the plating layer covering the pair of first surfaces being joined to the land portion by the solder,
the pair of second surfaces being arranged to overlap the land portion in the thickness direction,
a plurality of the conductor portions being provided, and
at least two or more conductor portions, out of the plurality of conductor portions, being arranged side by side in the second direction.

2. The wiring board of claim 1, wherein a distance in the second direction from at least either one of the second surfaces to an end of the land portion is shorter than a distance in the first direction from either one of the first surfaces to an end of the land portion.

3. The wiring board of claim 1, wherein the conductor portion is arranged over a plurality of the land portions separated from each other and joined to each of the plurality of land portions.

4. The wiring board of claim 3, wherein the solder is continuously arranged over the plurality of separated land portions between the board portion and the facing surface.

5. The wiring board of claim 1, wherein the entire facing surface of the conductor portion is provided to overlap the land portion.

6. The wiring board of claim 1, wherein an area of each of the pair of first surfaces is larger than an area of each of the pair of second surfaces.

7. The wiring board of claim 1, wherein the conductor portion has a longitudinal shape extending along a current flowing direction in a part where the conductor portion is joined.

8. The wiring board of claim 1, wherein a height of a fillet of the solder joined to at least either one of the first surfaces and the land portion is higher than a height of a center position in the thickness direction of the first surface joined to the fillet from the land portion.
